(19) United States
(12) Patent Application Publication
(10) Pub. No.: US 2005/0250336 A1
(43) Pub. Date: Nov. 10, 2005

(54) Semiconductor device and method for fabricating the same

(75) Inventor: Tsutomu Komatani, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/125,137

(22) Filed: May 10, 2005

(30) Foreign Application Priority Data
May 10, 2004 (JP) 2004-140431

(51) Int. Cl. H01L 21/00; H01L 21/302; H01L 21/461

(52) U.S. Cl. 438/706; 438/718; 438/735; 438/717; 438/736

(57) ABSTRACT

A method of fabricating a semiconductor device includes forming a film stack having a Ti film and a metal film containing Ni sequentially deposited on a surface of a substrate of a GaN based semiconductor, SiC, or sapphire, patterning the film stack to expose a portion of the surface of the etching substance, and dry etching an exposed portion of the surface of the etching substance. It is thus possible to enhance the adhesion between a dry etching mask and the surface of the etching substance. Peeling and cracking are suppressed and the highly accurate etching can be performed.

### BACKGROUND OF THE INVENTION

1. Field of the Invention

This invention generally relates to a method for fabricating semiconductor devices, and more particularly, to a technique for enabling a high-precision etching by improving the adhesion of a mask used for dry etching in the manufacturing process of a GaN based semiconductor device.

2. Description of the Related Art

According to the miniaturization of the semiconductor device, high voltage and high power density have been inevitably demanded. A nitride semiconductor as represented by gallium nitride (GaN), silicon carbide (SiC), and a wide band gap semiconductor device such as diamond are highly expected as possible solutions, and many studies have been done.

Especially, a nitride semiconductor material was developed as an optical device, yielding a spectacular result in a practical application as a blue light-emitting diode. The nitride semiconductor including GaN (hereinafter referred to as GaN based semiconductor) has characteristics of the wide band gap and direct transition. Additionally, the nitride semiconductor also has features of a large breakdown voltage, a high saturation drift velocity, excellent heat conductivity, and hetero junction characteristics. The nitride semiconductor is developed as an electronics device having a high power and high frequency.

It is extremely difficult to grow the bulk crystal having a big opening in the GaN based semiconductor. Therefore, the film is made by growing a buffer layer on a SiC or sapphire substrate and growing the buffer layer heteroepitaxially. The dry etching technique is one of the essential elemental technologies in the microfabrication in order to produce a GaN based semiconductor device. A plasma etching is mainly employed. For instance, a via hole is provided on a backside of the SiC substrate to establish a conduction, when an electronics device is formed with a GaN based semiconductor layer formed on the SiC substrate. The dry etching is required for forming a through-hole. Conventionally, a stainless mask has been employed for the etching mask.

FIGS. 1A through 1C schematically show an example of process of forming the via hole with the use of the stainless mask. A reference numeral 11 indicates an etching substance (substrate) of SiC or sapphire having the GaN based semiconductor layer provided on a main surface thereof. A reference numeral 12 indicates a stainless mask having an opening 12a for forming the via hole. Referring to FIG. 1A, the stainless mask 12 is bonded to a backside of the substrate 11. Referring to FIG. 1B, the stainless mask 12 is fixed by a clamp that is not shown. A portion of the substrate 11 is etched by injecting plasma from the opening 12a of the stainless mask 12. A via hole 13 is thus formed.

Japanese Patent Application Publication No. 8-274448 describes a patterning method using a protection film of a conductive metal thin film such as Ni or Ni—Cr alloy. The conductive metal thin film is used, as a dry etching mask to form a microscopic pattern on the substrate made of ceramic or plastic.

It is to be noted that there arises a problem in that peeling or cracking occurs while the dry etching is being performed on the SiC or sapphire substrate (or the GaN based semiconductor layer), when the stainless mask is used. This is because the adhesion is weak between the mask and the surface of the etching substance. There arises another problem in that the processing accuracy of the stainless mask is insufficient and the stainless mask cannot be used for the etching mask to form the microscopic pattern.

Even if a single-layered mask of Ni (or Ni alloy) that is excellent in tolerance to halogen plasma is used, the temperature of the etching surface rises 150° C. or more in the process of the high density plasma etching. Then, a Ni film is partially peeled from the surface of the etching substance or is cracked on the surface in the process of etching, resulting in the degradation of the etching accuracy. The inventors of the present invention have found for the first time that the aforementioned peeling or cracking is caused by the difference in thermal expansion coefficient between the etching material and the mask material of Ni.

With respect to the thermal expansion coefficients of the respective etching substances, SiC has 4.2×10⁻⁶/° C., Sapphire has 7.5×10⁻⁶/° C., and GaN has 5.6×10⁻⁶/° C. Ni used for the mask has 12.8×10⁻⁶/° C. The above-mentioned etching substances have the thermal expansion coefficients largely different from that of Ni. Therefore, when those etching substances are placed under the environment of the temperature of at least 150° C. at the time of the high-density plasma etching, the Ni film is peeled or cracked. This problem is also seen in other materials such as diamond and crystal. Diamond has a thermal expansion coefficient of 1.0×10⁻⁶/° C. Crystal has a thermal expansion coefficient of 0.5×10⁻⁶/° C.

It is difficult to form a desired through-hole, if the conventional mask is employed for dry etching, because the mask is peeled or cracked in the dry etching process, as described. It is difficult to form the via hole having an appropriate shape on the GaN based semiconductor device, in particular.

### SUMMARY OF THE INVENTION

The present invention has been made in view of the above circumstances. It is a general object of the present invention to provide a method for fabricating a GaN based semiconductor device so as to enable a highly accurate etching process.

A more specific object of the present invention is to enhance the adhesion between a mask for dry etching and a surface of a dry etching substance and suppress peeling and cracking on an etching surface with the use of the aforementioned method.

According to one aspect of the present invention, preferably, there is provided a method of fabricating a semiconductor device comprising: forming a film stack having a Ti film and a metal film containing Ni sequentially deposited on a surface of an etching substance of a GaN based semiconductor, SiC, or sapphire; patterning the film stack to expose a portion of the surface of the etching substance; and dry etching an exposed portion of the surface of the etching substance.

According to another aspect of the present invention, preferably, there is provided a semiconductor device comprising a layer made of a GaN based semiconductor, SiC, or sapphire, wherein the layer is selectively dry etched with a mask of a film stack in which a Ti film and a metal film containing Ni are sequentially formed.

The Ti film and the Ni film are sequentially formed on the substrate of GaN based semiconductor layer, SiC, or sapphire, which is an etching substance, by a vacuum evaporation method. The film stack is patterned with a photolithographic method to form the mask. The Ni alloy film is formed on the surface of the etching substance by a diffusion plate method. The Ni alloy film is patterned with the photolithographic method to form the mask. The effect of suppressing the distortion is obtainable by the Ti film and the Ni alloy film formed by the diffusion plate method. It is thus possible to enhance the adhesion between a dry etching mask and the surface of the etching substance. Peeling and cracking are suppressed and the highly accurate etching can be performed.

### BRIEF DESCRIPTION OF THE DRAWINGS

Preferred embodiments of the present invention will be described in detail with reference to the following drawings, wherein:

FIGS. 1A through 1C schematically show an example of process of forming a via hole with the use of a stainless mask;

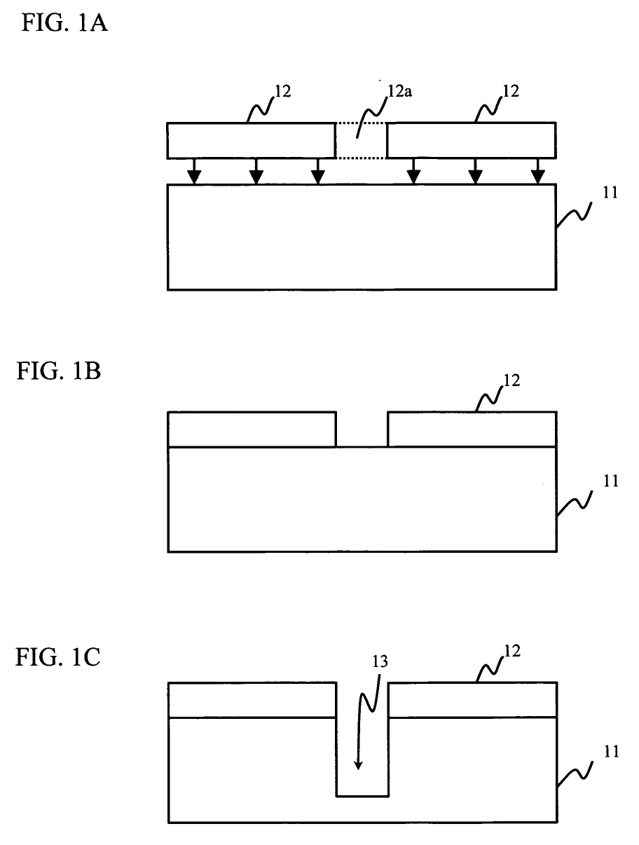

FIGS. 2A through 2F illustrate a process of a first embodiment of the present invention;

FIG. 3 is a graph showing dependence of the gain (vertical line) on the frequency (horizontal line) in a GaN based HEMT;

FIGS. 4A through 4D illustrate a process in accordance with a second and fourth embodiments of the present invention; and

FIGS. 5A through 5D illustrate the process in accordance with a third embodiment of the present invention.

### DESCRIPTION OF THE PREFERRED EMBODIMENTS

A description will now be given, with reference to the accompanying drawings, of embodiments of the present invention.

A first dry etching mask of the present invention includes a GaN based semiconductor layer, SiC, or sapphire, which is an etching substance. A Ti film and a Ni film are deposited sequentially in this order, and a film stack is formed on the substance. The film stack is patterned by a photolithographic method in the dry etching process. For example, when the Sic substrate is etched, SiC has a thermal expansion coefficient of 4.2×10⁻⁶/° C. and Ni has a thermal expansion coefficient of 12.8×10⁻⁶/° C. Therefore, there is a large difference in the thermal expansion coefficient between the two substances. However, a distortion, which is generated according to the thermal expansion caused resulting from the temperature rise in the dry etching process, is alleviated by arranging a Ti film having a thermal expansion coefficient of 9×10⁻⁶/° C. between the two substances. This increases the adhesion between the surface of the SiC substrate and the mask, and suppresses the peeling and cracking.

Here, the above-mentioned Ti film undergoes the etching process with sandwiched between the surface of the etching substance and the Ni film. If the Ti film is too thick, a side face of the Ti film will be etched and an etched shape thereof will result in an undesirable one. On the contrary, if the Ti film is too thin, the distortion caused by the difference in the thermal expansion coefficient will not be suppressed sufficiently. In view of the aforementioned circumstances, preferably, the Ti film has a thickness of 10 to 30 nm. More preferably, the Ti film has a thickness of around 20 nm.

A second dry etching mask of the present invention includes the Ti film formed on the etching substance and the Ni alloy film formed on the Ti film by a diffusion plate method. Then, the Ni alloy film is patterned by the photolithographic method. Moreover, the Ni film may be formed by the diffusion plate method on the surface of the etching substance that has been coated with a patterned photoresist, and the mask may be formed on an opening region for resist mask.

The Ni alloy denotes an alloy of Ni and one of Ag, Sn, P, and B. The diffusion plate method is used for diffusing the metals separately and stacking the metals on the surface of the etching substance. This diffusion plating may employ either electroless plating or electrolytic plating. With the electroless plating, the metal having an equal thickness is deposited on the surface of the etching substance by chemical reduction. With the electrolytic plating, the metal for plating is deposited on the surface of the etching substance by conducting the etching substance as a cathode in the electrolytic solution to deposit a plated metal on the surface of the etching substance.

The thermal expansion coefficient of the alloy film is approximately 12.8×10⁻⁶/° C., when the Ni alloy is simply plated in accordance with the conventional technique. In contrast, the thermal expansion coefficient of the Ni alloy film is reduced to 9−10×10⁻⁶/° C., when the Ni alloy film is formed by the diffusion plate method in accordance with the present invention. Thus, the difference in the thermal expansion coefficient between the mask and the etching substance is reduced by 30 to 40 percent, and thereby the peeling or cracking on the etching substance is also suppressed. Preferably, the composition ratio of Ag or Sn contained in the Ni alloy is 10 to 20 percent, and the composition ratio of P or B contained in the Ni alloy is 8 to 10 percent.

Additionally, the aforementioned Ni alloy film formed by the diffusion plating may be used instead of the Ni film of the first dry etching mask of the present invention. A synergistic effect is generated with this film stack containing the Ni alloy film, the effect of suppressing the distortion of the Ti film and the effect of suppressing the distortion of the Ni alloy film formed by the diffusion plating provided on the Ti film, and the mask having a difficulty of peeling or cracking is obtainable.

Under the normal plasma etching conditions, the temperature of the etching substance rises to at least 150° C. The effect of suppressing the peeling or cracking is seen in the temperature range to 200° C. with the first and second masks. Moreover, when the Ni alloy film formed by the diffusion plating is employed for the Ni film in the first etching mask of Ni/Ti film stack, the effect of suppressing the peeling and cracking is seen in the temperature ranging to 300° C.

The effect of suppressing the peeling and cracking has been confirmed with the use of the etching masks of the present invention, when the Ni layer has a thickness of 10 μm in the metal film containing Ni or the Ni alloy film formed by the diffusion plating.

A description will now be given, with reference to the accompanying drawings, of embodiments of the present invention in detail.

### First Embodiment

A first embodiment of the present invention is an example of forming the via hole with the first dray etching mask.

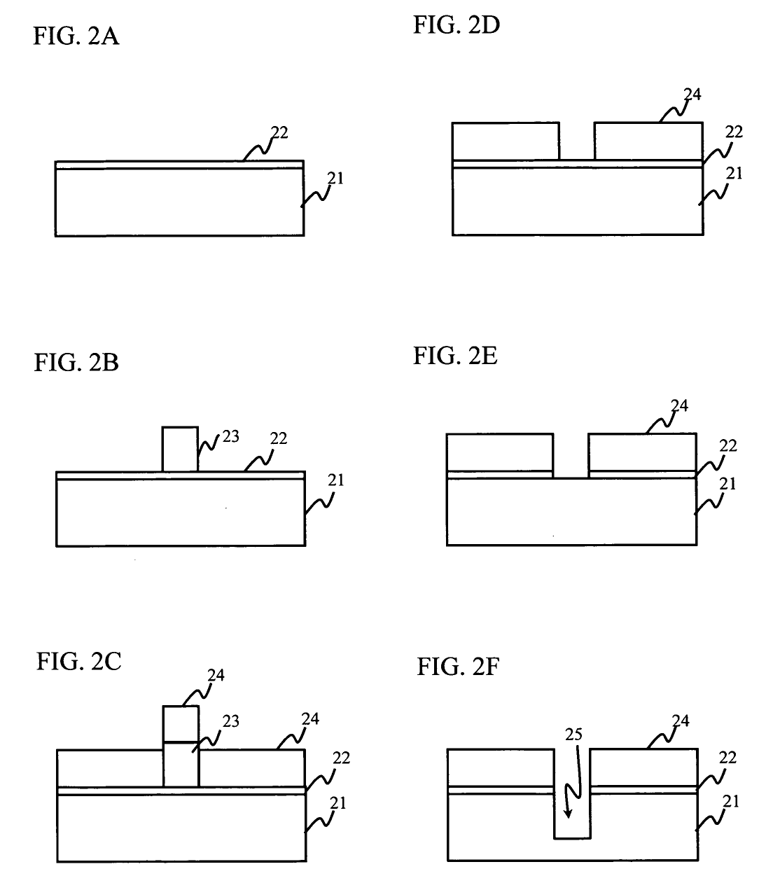

FIGS. 2A through 2F illustrate a process of the first embodiment of the present invention. Referring to FIG. 2A, a Ti film 22 having a thickness of 20 nm is formed on the surface of an etching substance (substrate) 21 of the GaN based semiconductor layer, SiC, or sapphire. The GaN based semiconductor layer is, for example, InGaN, AlGaN, InGaNP, or the like. Referring to FIG. 2B, a patterned photoresist mask 23 is formed on the Ti film 22. Referring to FIG. 2C, a Ni film 24 having a thickness of 4 μm is formed on an opening region of the photoresist mask 23. Referring to FIG. 2D, the photoresist mask 23 is removed. The Ti film 22 and the Ni film 24 are deposited by the vacuum evaporation method or sputtering method.

After the photoresist mask 23 is removed, only the Ni film 24 is formed on the Ti film 22. The opening region of the Ti film 22 is selectively dry etched at a low energy with the use of the Ni film 24 serving as a mask. Referring to FIG. 2E, the backside of the etching substance 21 is exposed.

Finally, plasma is injected from the opening region of the Ni/Ti films serving as the mask, and a via hole 25 is formed by dry etching. The dry etching is performed with a plasma-etching device used for Reactive Ion Etching (RIE), Electron Cyclotron Resonance (ECR) etching, or Inductively Coupled Plasma (ICP) etching. An etching gas is selected according to the material of the substrate to be etched. If an ICP etching device is employed, a great power of plasma can be excited by a large-sized multi-turn inductively coupled coil, and the dry etching is performed by high-density plasma.

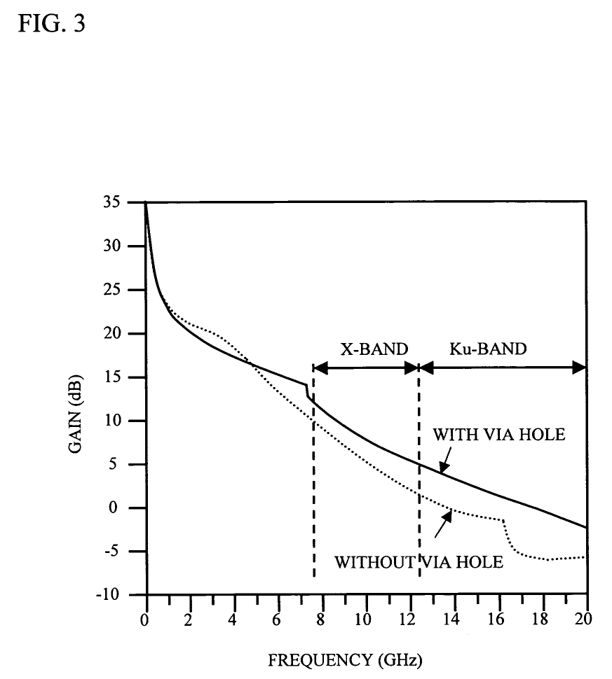

FIG. 3 is a graph showing dependence of the gain (vertical line) on the frequency (horizontal line) in a GaN based HEMT, in which the via hole is formed with the above-mentioned ICP dry etching to provide a source electrode. For comparison, FIG. 3 also includes the dependency of another HEMT in which the via hole is not provided. These HEMTs are provided on GaN layers formed on the SiC substrates. As shown in FIG. 3, a high gain of 2 dB or more is obtained in the X-band region and 3 dB or more is obtained in the Ku-band region of the GaN based HEMT connected to ground through the source electrode provided in the via hole. The device characteristics are largely improved.

The via hole 25 having a depth of 150 μm is formed in each of the substrates such as SiC, sapphire, and crystal together with the thick-film layer of the GaN based semiconductor (InGaN and AlGaN). As results of testing, it has been confirmed that the etching selectivity of Ni is at least 30 in any substrate and the via hole having an aspect ratio of 5 can be formed.

### Second Embodiment

A second embodiment of the present invention is also an example of forming the via hole with the use of the first dry etching mask. However, the forming process of the Ni/Ti film stack serving as the mask in the second embodiment of the present invention is different from that of the first embodiment of the present invention.

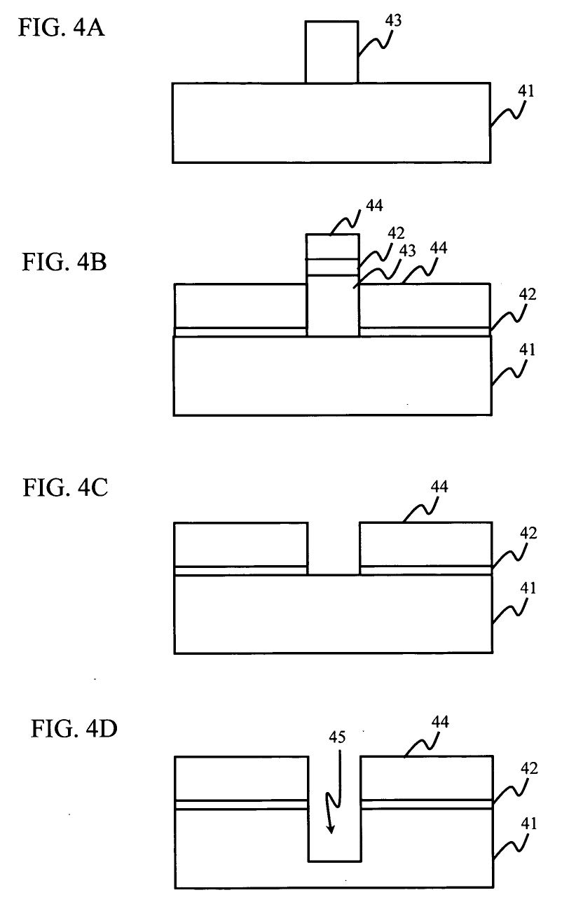

FIGS. 4A through 4D illustrate the forming process in accordance with the second embodiment of the present invention. Referring to FIG. 4A, a patterned photoresist mask 43 is formed on an etching substance (substrate) 41 of the GaN based semiconductor layer (such as InGaN, AlGaN, InGaNP, or the like), SiC, or sapphire. Referring to FIG. 4B, a Ti film 42 having a thickness of 20 nm and a Ni film 44 having a thickness of 4 μm is sequentially stacked. The Ti film 42 and the Ni film 44 are formed by the vacuum evaporation method or the sputtering method.

Referring to FIG. 4C, the photoresist mask 43 is removed after the Ni/Ti film stack is formed. Referring to FIG. 4D, a via hole 45 is formed by injecting plasma from the opening region of the Ni/Ti film stack to selectively dry etch the etching substance 41. This dry etching is performed with the plasma etching device for RIE, ECR, or ICP etching.

The GaN based HEMT having the via hole formed in this manner also has a high gain same as that shown in FIG. 3. The via hole 45 having a depth of 150 μm in accordance with the second embodiment of the present invention has been tested with the use of various substrates such as SiC, sapphire, and crystal and the GaN based semiconductor thick film (such as InGaN and AlGaN). The test results have been same as those of the first embodiment of the present invention. Thus, it has been confirmed that the etching selectivity of Ni is at least 30 in any etching substance and the via hole having an aspect ratio of 5 can be formed.

### Third Embodiment

A third embodiment of the present invention is an example of forming the via hole with the use of the second dry etching mask.

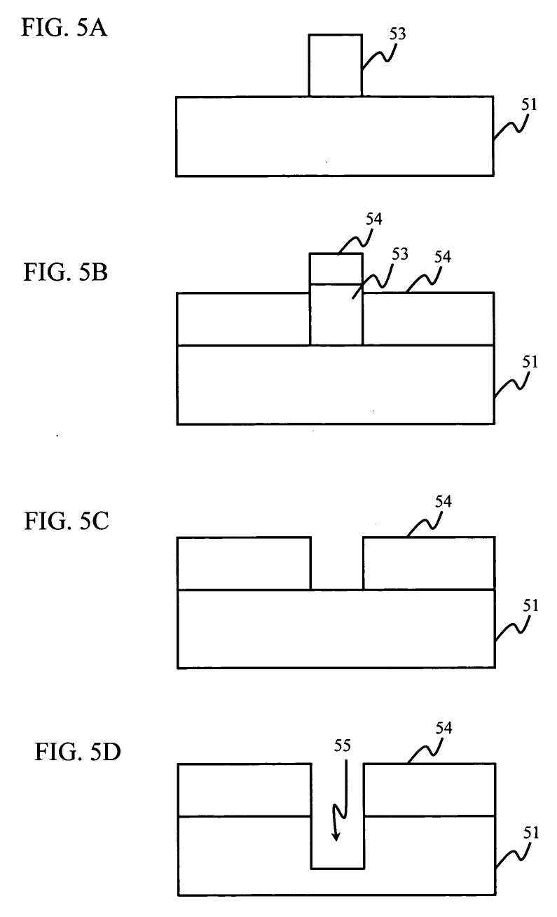

FIGS. 5A through 5D illustrate the process in accordance with the third embodiment of the present invention. Referring to FIG. 5A, a patterned photoresist mask 53 is formed on a surface of an etching substance (substrate) 51 of the GaN based semiconductor layer (such as InGaN, AlGaN, InGaNP, or the like), SiC, or sapphire. Referring to FIG. 5B, a Ni alloy film 54 having a thickness of 5 μm is formed by the diffusion plate method.

Referring to FIG. 5C, the photoresist mask 53 is removed after the Ni alloy film is formed. Referring to FIG. 5D, a via hole 55 is formed by injecting plasma from the opening region of the Ni alloy film so as to dry etch the etching substance 51. This dry etching is performed with the plasma etching device for RIE, ECR, or ICP etching.

The GaN based HEMT having the via hole formed in this manner also has a high gain same as that shown in FIG. 3. The via hole 4 having a depth of 150 μm in accordance with the third embodiment of the present invention has been tested with the use of various substrates such as SiC, sapphire, and crystal and the GaN based semiconductor thick film (such as InGaN and AlGaN). The test results have been same as those of the first embodiment of the present invention. Thus, it has been confirmed that the etching selectivity of Ni is at least 30 in any substrate and the via hole having an aspect ratio of 5 can be formed.

### Fourth Embodiment

A fourth embodiment of the present invention is an example of employing the Ni alloy film described in the third embodiment of the present invention for the Ni film in the first dry etching mask.

The process of the fourth embodiment of the present invention is same as shown in FIGS. 4A through 4D. Referring to FIG. 4A, the patterned photoresist mask 43 is formed on the surface of the etching substance 41 of the GaN based semiconductor layer (such as InGaN, AlGaN, InGaNP, or the like), SiC, or sapphire. Referring to FIG. 4B, the Ti film 42 having a thickness of 20 nm and a Ni alloy film 44 having a thickness of 4 μm is sequentially stacked. The Ni alloy film 44 is formed by the vacuum evaporation method in accordance with the fourth embodiment of the present invention. The Ni alloy film 44 has a thickness of 4 μm, and is an Ag—Ni alloy having a mother layer of Ni and an inclusion of diffused Ag.

Referring to FIG. 4C, the photoresist mask 43 is removed after the Ni alloy film 44 is formed by the diffusion plate method. Referring to FIG. 4D, the via hole 45 is dry etched in the etching substance 41 by injecting plasma from the opening region in the Ni alloy film 44. This dry etching is performed with the plasma etching device for RIE, ECR, or ICP etching.

The GaN based HEMT having the via hole formed in this manner also has a high gain same as that shown in FIG. 3. The via hole 45 having a depth of 150 μm in accordance with the fourth embodiment of the present invention has been tested with the use of various substrates such as SiC, sapphire, and crystal and the GaN based semiconductor thick film such as InGaN and AlGaN. The test results have been same as those of the first embodiment of the present invention. Thus, it has been confirmed that the etching selectivity of Ni is at least 30 in any substrate and the via hole having an aspect ratio of 5 can be formed.

The film-forming process and patterning process in the etching mask forming procedure has been described. However, the orders of the processes described above are examples, and may be changed as necessary.

On the method of fabricating the semiconductor device, patterning the film stack may comprise providing a mask on the etching substance and selectively removing the mask by a liftoff process after forming the film stack.

On the method of fabricating the semiconductor device, the metal film containing Ni may be a plated film that is made of Ni or a metal containing Ni.

The present invention is capable of providing the dry etching mask having a high adhesion to the etching substance such as GaN, SiC, sapphire, crystal, or the like, and also providing the GaN based semiconductor produced with high processing accuracy.

The present invention is not limited to the above-mentioned embodiments, and other embodiments, variations and modifications may be made without departing from the scope of the present invention.

The present invention is based on Japanese Patent Application No. 2004-140431 filed on May 10, 2004, the entire disclosure of which is hereby incorporated by reference.

1. A method of fabricating a semiconductor device comprising:
forming a film stack having a Ti film and a metal film containing Ni sequentially deposited on a surface of an etching substance of a GaN based semiconductor, SiC, or sapphire;
patterning the film stack to expose a portion of the surface of the etching substance; and
dry etching an exposed portion of the surface of the etching substance.

2. The method as claimed in claim 1, wherein patterning the film stack comprises providing a mask on the etching substance and selectively removing the mask by a liftoff process after forming the film stack.

3. The method as claimed in claim 1, wherein dry etching the exposed portion uses any one of reactive ion etching, electron cyclotron resonance etching, and inductively coupled plasma etching.

4. The method as claimed in claim 1, wherein the GaN based semiconductor comprises any one of InGaN, AlGaN and InGaNP.

5. The method as claimed in claim 1, wherein the Ti film and the metal film containing Ni are formed by a vacuum evaporation method or a sputtering method.

6. The method as claimed in claim 1, wherein the Ti film has a thickness of 10 to 30 nm.

7. The method as claimed in claim 6, wherein the Ti film has a thickness of approximately 20 nm.

8. The method as claimed in claim 1, wherein the metal film containing Ni has a thickness of at most 10 μm.

9. The method as claimed in claim 1, wherein the metal film containing Ni is a plated film that is made of Ni or a metal containing Ni.

10. The method as claimed in claim 9, wherein the metal film containing Ni is composed of Ni and another metal containing at least one of Ag, Sn, P, and B.

11. The method as claimed in claim 10, wherein said another metal contains Ag or Sn with a composition ratio of 10 to 20.

12. The method as claimed in claim 10, wherein said another metal contains P or B with a composition ratio of 8 to 10 percent.

13. A semiconductor device comprising a layer made of a GaN based semiconductor, SiC, or sapphire, wherein the layer is selectively dry etched with a mask of a film stack in which a Ti film and a metal film containing Ni are sequentially formed.
